(19) United States
(12) Patent Application Publication
(10) Pub. No.: US 2002/0001954 A1
(43) Pub. Date: Jan. 3, 2002

(54) Dual damascene process

(76) Inventor: Shih-Ying Hsu, Hsin-Chu City (TW)

Correspondence Address: POWELL, GOLDSTEIN, FRAZER & MURPHY LLP, P.O. BOX 97223, WASHINGTON, DC, 20090-7223, US

(21) Appl. No.: 09/824,513

(22) Filed: Apr. 2, 2001

Related U.S. Application Data
(63) Continuation-in-part of application No. 09/324,467, filed on Jun. 2, 1999, now abandoned.

(51) Int. Cl. H01L 21/302; H01L 21/461

(52) U.S. Cl. 438/692

(57) ABSTRACT

A process for forming an adapted small dimension and more quality fabrication is disclosed. One embodiment comprises following: provide a substrate, then form a first dielectric layer and a first photoresist over the substrate. Sequentially, remove partial first dielectric layer until a portion of substrate is exposed. Next, form a first inter-metal dielectric layer over the substrate and treat the first inter-metal dielectric layer by a planarization process. Then, form a second dielectric layer and a second photoresist formed over the first inter-metal dielectric layer. Consequently, remove partial the second dielectric layer until a portion of surface of the first inter-metal dielectric layer is exposed. The, form a second inter-metal dielectric layer over the first inter-metal dielectric layer which followed by a planarization process. Next, remove the second dielectric layer and the first dielectric layer to form a hole. After hole is formed, form a barrier layer on the hole and then fill the hole by metal.

This application is a continuation-in-part of U.S. patent application Ser. No. 09/324,467, filed May 28, 1999.

### BACKGROUND OF THE INVENTION

1. Field of the Invention

The present invention relates to a dual damascene process, and more particularly, to a dual damascene process which significantly reduce loss of damascene profile.

2. Description of the Prior Art

Damascene is a jewelry fabrication term that has been adopted to refer to a microelectronics metallization process where interconnect leads are recessed in an insulator by patterning troughs in the planar dielectric and filling the troughs with metal, e.g., by collimated sputtering or CVD. The metal in the “field” is then removed by chemical mechanical polishing process, leaving troughs filled with metal. The damascene wiring technique has been used with many different wiring materials, including W, AL alloys, Cu, and Ag.

The main advantage of damascene is that it eliminates the need for etching to define the metal pattern, increasing the flexibility in the metal composition. Dry etching of AL—Cu alloys, for example, becomes more difficult as the copper content increases. When no etching required, a larger amount of copper or other elements can be added to aluminum to improve the metal immunity to electromigration or stress migration.

Moreover, because metallization is getting complex for contemporary semiconductor devices, dual damascene, which forms studs and interconnects with one planarization step, is broadly used to increase the density, performance, and reliability in a fully integrated wiring technology. Without question, by forming studs and interconnects with the same material, the number of interfaces between dissimilar materials is reduced, and then reliability of the metallization system is increased.

One popular conventional technology for forming a dual damascene structure is briefly includes following essential steps:

As FIG. 1A shows, form first dielectric layer 11, middle layer 12, and second dielectric layer 13 on substrate 10 in sequence. Both first dielectric layer 11 and second dielectric layer 13 usually are oxide layers or any dielectric layer which has low dielectric constant, middle layer 12 usually is silicon nitride layer or any layer which has a larger etch selectivity form adjacent layers 11 and/or 13, and thickness of middle layer 12 usually is thinner than each of adjacent layers 11 and 13.

As FIG. 1B shows, remove part of second dielectric layer 13 to form first hole 14, where part of middle layer 12 usually also is removed for middle layer 12 usually is used to provide required stop layer while part of second dielectric layer 13 are removed.

As FIG. 1C shows, remove part of first dielectric 11 to form second hole 15, which is totally overlaid by first hole 14 and cross-sectional area of second hole 15 usually is smaller than cross-sectional area of first hole 14.

As FIG. 1D shows, fills both first hole 14 and second hole 15 by conductor material 16 to form a damascene structure. Of course, conductor material 16 usually is planarized to expose top surface of second dielectric layer 13.

Another popular conventional technology for forming a dual damascene structure briefly includes following essential steps:

As FIG. 2A shows, form first dielectric layer 21 and middle layer 22 on substrate 20 in sequence. First dielectric layer 21 usually is oxide layer or any dielectric layer with low dielectric constant, middle layer 22 usually is silicon nitride layer, and thickness of middle layer 22 usually is thinner than first dielectric layer 21.

As FIG. 2B shows, remove part of first dielectric layer 21 to form first hole 23 which expose part of substrate 20.

As FIG. 2C shows, form second dielectric layer 24 on middle layer 22, second dielectric layer 24 also fill first hole 23. Where, second dielectric layer 24 usually is oxide layer or any layer with low dielectric constant, and the etch selectivity between second dielectric layer 23 and middle layer 22 usually is large enough to let middle layer 22 could be used as the etch stop layer of second dielectric layer 23.

As FIG. 2D shows, remove part of second dielectric layer 24 to form second hole 25 which totally overlay first holes 23. Where part of middle layer 22 usually also is removed for middle layer 22 usually is used to provide required stop layer while part of second dielectric layer 13 are removed.

As FIG. 2E shows, fills both first hole 23 and second hole 25 by conductor material 26 to form a damascene structure. Of course, conductor material 26 usually is planarized to expose top surface of second dielectric layer 24.

In short, as FIG. 3A shows, essential spirit of conventional technologies for forming a dual damascene structure could be briefly summarized as following steps: as background block 31 shows, form dielectric layers without any hole or surrounded structure; as hole block 32 shows, form a hole which has the profile of dual damascene structure in dielectric layers; as conductor block 33 shows, fill the hole by conductor material.

Obviously, conventional technologies for forming a dual damascene structure at least have following disadvantage: First, two holes are formed separated, then cost is increased and efficiency is decreased. Second, middle layer is desired to prove stop layer during process for forming hole, because dielectric constant usually is higher than adjacent layers, parasitic capacitor around dual damascene structure is negligible. Third, etch selectivity between middle layer and adjacent dielectric layers is hard to be controlled, and then profile of dual damascene structure is lost.

### SUMMARY OF THE INVENTION

According to previous discussion, one main object of the present invention is to provide a novel dual damascene process, which effectively prevent unavoidable disadvantages of conventional technologies for forming a dual damascene structure.

Another object of the invention is to provide a practical method for production line to form dual damascene structure.

One preferred embodiment is a dual damascene process for forming a damascene structure, said damascene structure is a combination of a lower part and an upper part which is wider than lower part. The embodiment at least includes following essential steps: provide a substrate; form a first model structure on the substrate, where profile of first model structure is equal to profile of lower part; form a first dielectric layer on part of substrate which is not covered by first model structure, where height of first dielectric layer is equal to height of first model structure; form a second model structure on both first model structure and part of first dielectric layer, where profile of second model structure is equal to profile of upper part; form a second dielectric layer on part of first dielectric layer which is not covered by second model structure, where height of second dielectric layer is equal to height of second model structure; remove both first model structure and second model structure, such that a hole is formed in both first dielectric layer and second dielectric layer; fill hole by a conductor layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A through FIG. 1D are cross-sectional illustrations of various stages of one conventional process for forming a dual damascene process;

FIG. 2A through FIG. 2E are cross-sectional illustrations of various stages of another conventional process for forming a dual damascene process;

FIG. 3A and FIG. 3B are tables for briefly comparing essential concepts of conventional technologies with essential concepts of this present invention;

FIG. 4A through FIG. 4F are cross-sectional illustrations of various stages of one preferred embodiment of this invention; and

FIG. 5 is a briefly flow-chart of another preferred embodiment of this invention.

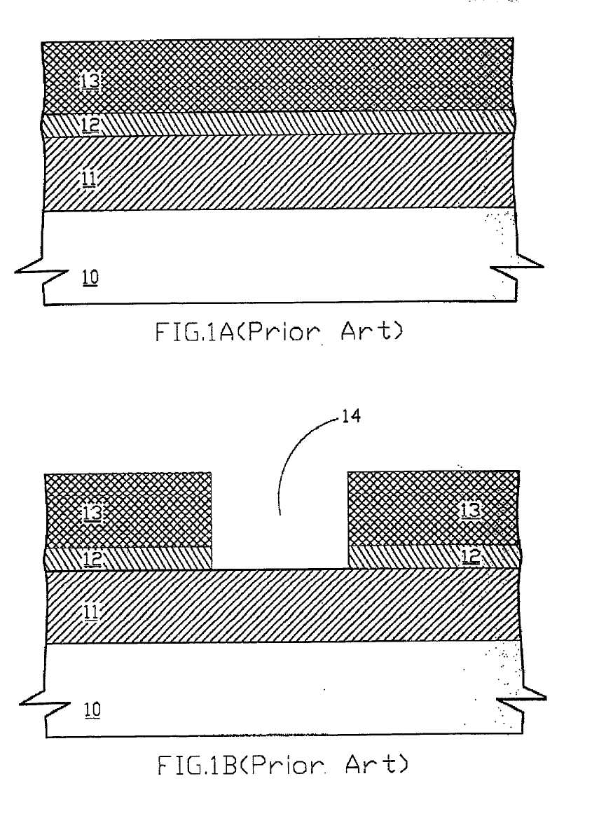

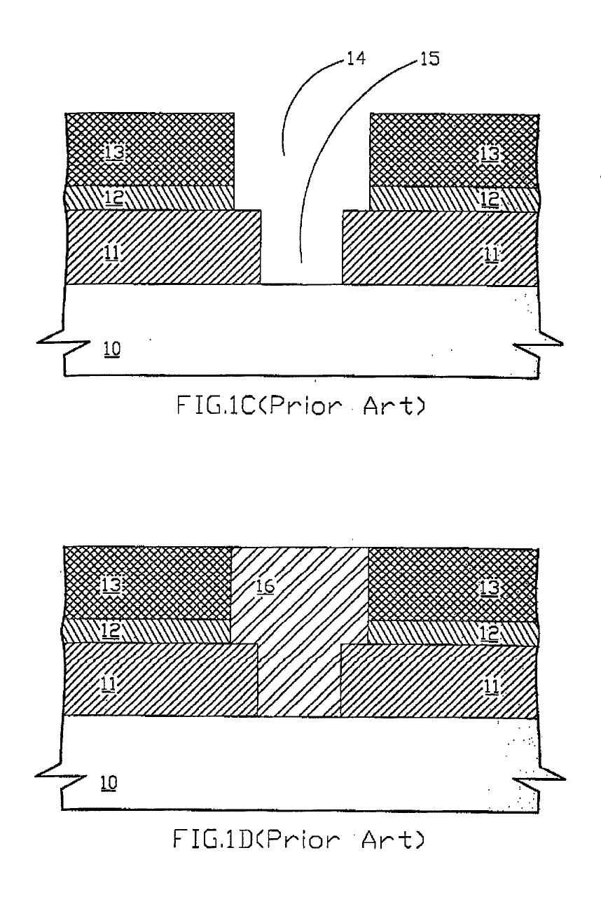

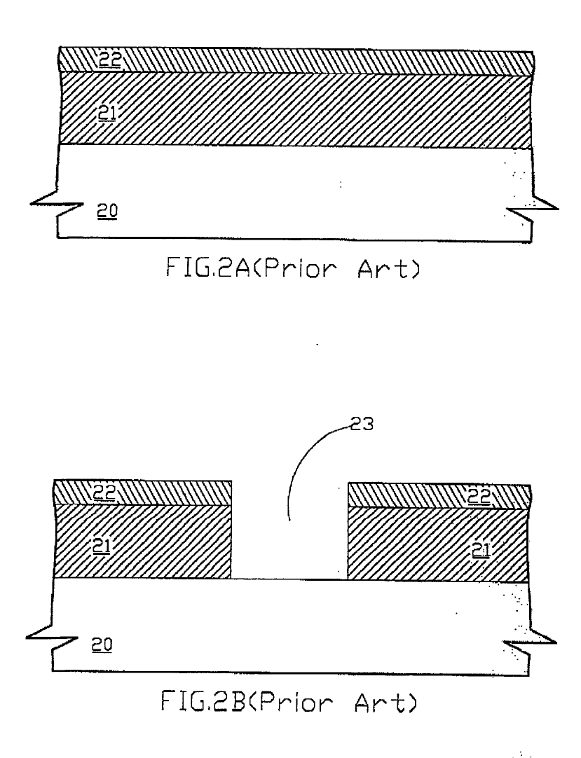

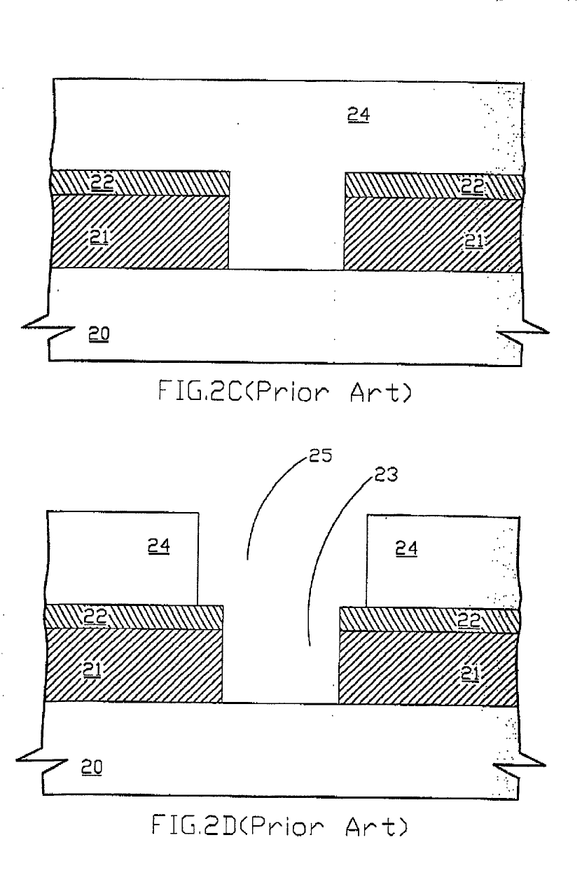

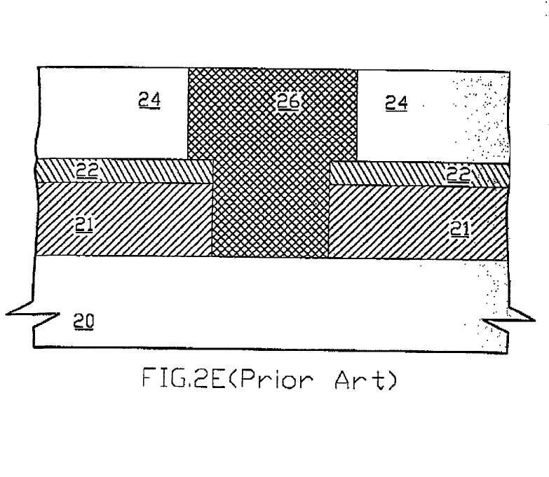

### DESCRIPTION OF THE PREFERRED EMBODIMENT

Applicant of this present invention carefully analysis conventional technologies for forming a dual damascene structure and find an important clue for preventing above disadvantage: because middle only (stop layer) is desired forming two close holes in sequence and is not desired while two close holes are formed simultaneously. In other words, whenever one hole which has profile of upper part of dual damascene structure and another hole which has profile of lower part of dual damascene structure are formed at the same time without application of middle layer (stop layer), not only parasitic capacitor is reduced but also profile lose induced by difficulty for controlling etch selectivity is reduced. Moreover, because only one removing process is required to form one hole but not two removing processes are required to form two holes, cost is decreased and efficiency is increased.

With the indication of this clue, the Applicant provide a preferred embodiment that is a dual damascene process for forming a damascene structure which could be divided into a narrower lower part and a wider upper part. The preferred embodiment at least includes following essential steps:

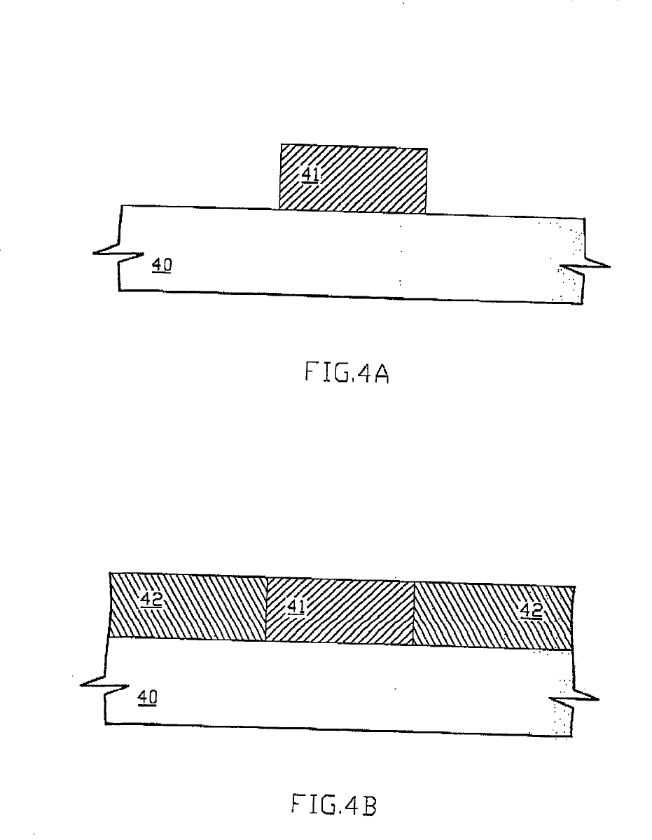

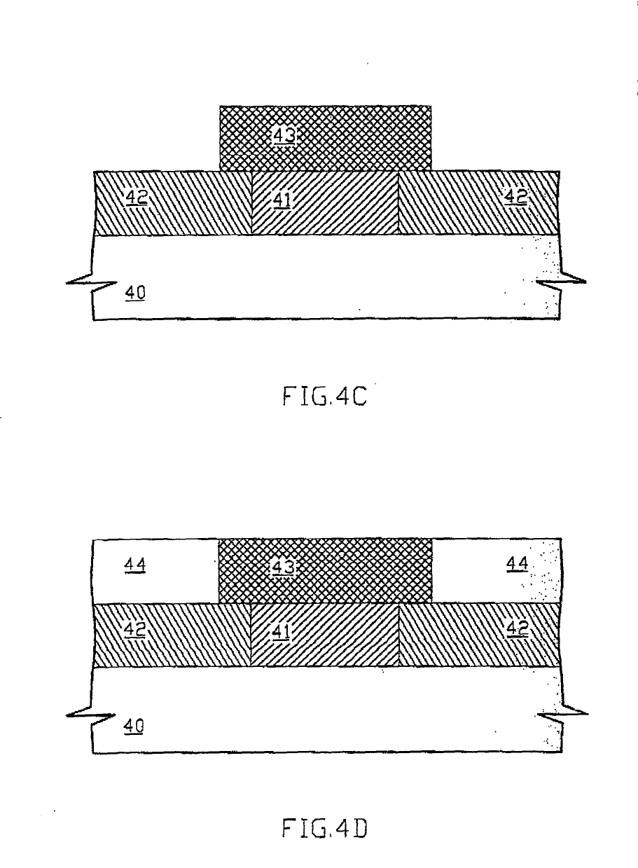

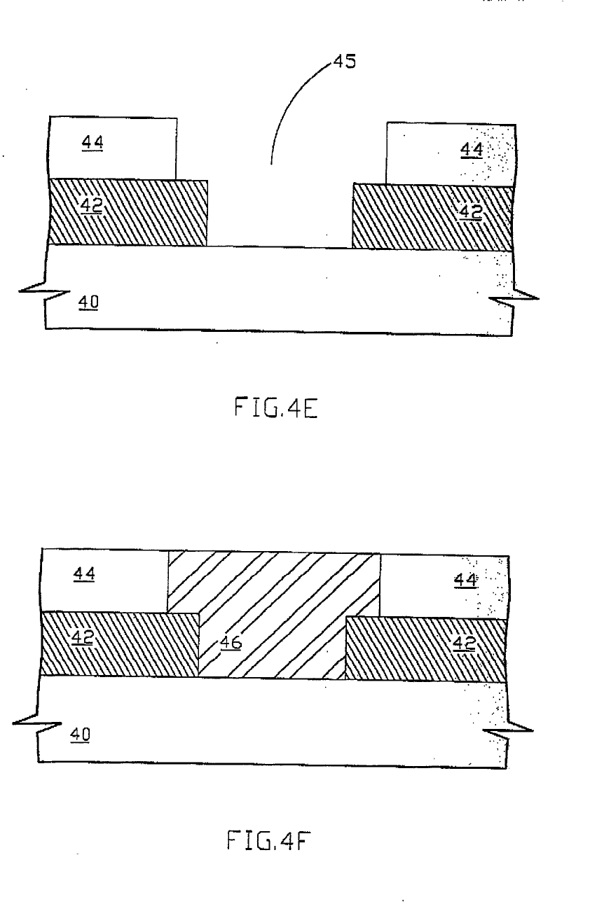

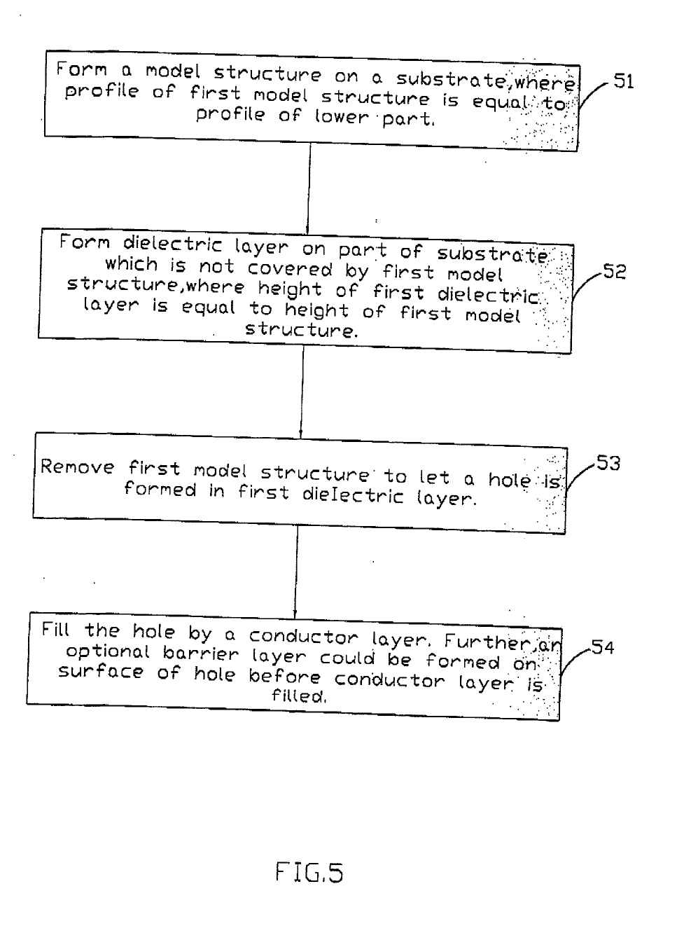

As FIG. 4a shows, provide substrate 40 and form first model structure 41 on substrate 40, where profile of first model structure 41 is equal to profile of the lower part.

As FIG. 4B shows, form first dielectric layer 42 on part of substrate 40, such that substrate 20 is totally covered by both first model structure 41 and first dielectric layer 42. Height of first dielectric layer 42 is briefly equal to height of first model structure 41.

As FIG. 4C shows, form second model structure 43 on both first model structure 41 and part of first dielectric layer 42, where profile of second model structure 43 is equal to profile of upper part.

As FIG. 4D shows, form second dielectric layer 44 on part of first dielectric layer 41 which is not covered by second model structure 43, where height of second dielectric layer 44 is briefly equal to height of second model structure 43.

As FIG. 4E shows, remove second model structure 43 and first model structure 41, such that hole 45 is formed in both first dielectric layer 42 and second dielectric layer 44. Second model structure 43 usually is removed by a wet etching process and first model structure 41 also usually is removed by a wet etching process. Moreover, second model structure 43 and first model structure 41 usually are removed by the same wet etching process to simply fabrication of this embodiment, which means that material of second model structure 43 is similar, or even equal, to material of first model structure 41. Further, after wet etching process (es) is finished, a blanket dry etching process usually is performed to ensure both structures 41/43 are totally removed.

As FIG. 4F shows, fill hole 45 by conductor layer 46. Surely, to improve quality of dual damascene structure, an optional barrier layer, not shown in FIG. 4F, usually is formed on surface of hole before hole is filled by conductor layer 46.

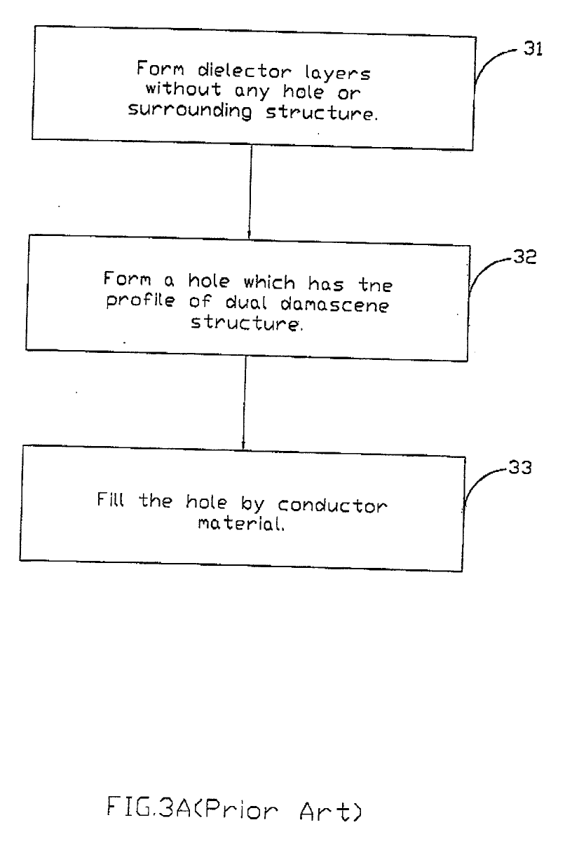

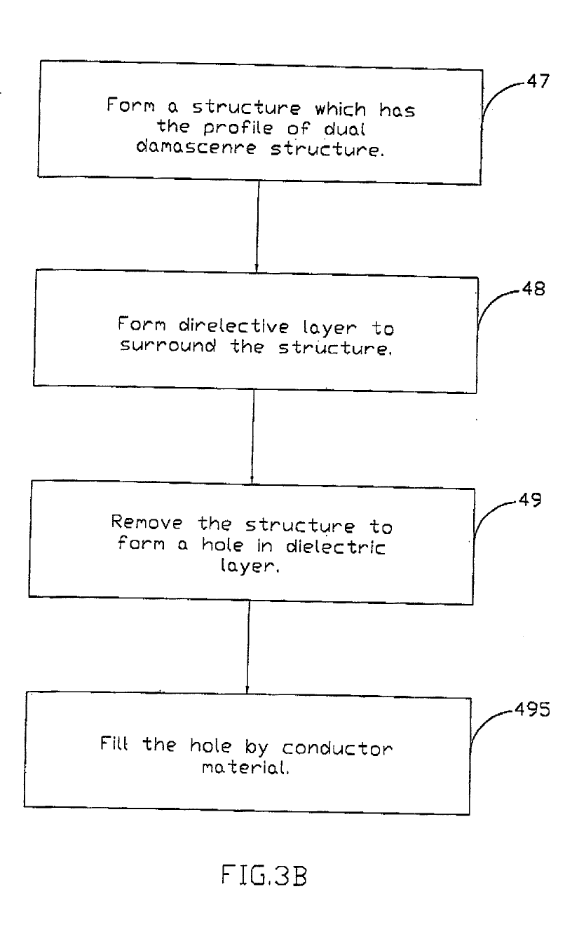

Accordingly to this embodiment, as FIG. 3B shows, essential spirit of this present invention could be briefly summarized as following steps: as hole profile block 47 shows, form a structure which has profile of dual damascene structure; as surrounding block 48 shows, form dielectric layers to surround the structure; as hole block 49 shows, remove this structure to form a hole; as conductor block 495 shows, and then fill the hole by conductor material.

Furthermore, because essential spirit of this invention is not limited by details of profile of dual damascene structure, it is acceptable to let cross-sectional area of upper part is equal to cross-sectional area of lower part, which is the case of damascene structure. In fact, if the technology problems could be solved, this invention also allow cross-sectional area of upper part is smaller than cross-sectional area of lower part which means second hole could not totally overlay first hole.

Accordingly, another preferred embodiment of this invention is a damascene process for forming a damascene structure, at least includes following basic steps:

As model block 51 shows, form a model structure on a substrate, where profile of first model structure is equal to profile of lower part.

As dielectric layer block 52 shows, form dielectric layer on part of substrate which is not covered by first model structure, where height of first dielectric layer is equal to height of first model structure.

As hole block 53 shows, remove first model structure to let a hole is formed in first dielectric layer.

As material block 54 shows, fill the hole by a conductor layer. Further, an optional barrier layer could be formed on surface of hole before conductor layer is filled.

Another preferred embodiment is a practical application of this present invention.

First of all, first silicon nitride layer 61, which has a thickness about 8000 to 11000 angstroms, is formed, for example by a chemical vapor deposition (CVD) process, on substrate 60. However, practical thickness of first silicon nitride layer 61 depends on the required dimension of the required dual damascene structure. Subsequently, photoresist 62 is formed and patterned on first silicon nitride layer 61 by using photolithography techniques to define location of the lower part of dual damascene structure on substrate 60. Where profile of photoresist is similar to a continue structure.

Sequentially, use photoresist 62 as a mask to let first silicon nitride layer 62 is isotroptically etched, such that a portion of underlying substrate 60 are exposed and residual first silicon nitride layer 61 has the profile of lower part of corresponding dual damascene structure. Then, remove photoresist 62. Next, form first inter-metal dielectric layer 63 on substrate 60 by, for example, conventional plasma enhanced chemical vapor deposition (PECVD) or high-density plasma chemical vapor deposition (HDPCVD). Thickness of first inter-metal dielectric layer 63 is preferably about 12000-15000 angstroms. And then, first inter-metal dielectric layer 63 is removed, or called as planarized, until the upper surface of residual first silicon nitride layer 61 is exposited, generally followed a planarization process such as chemical mechanical polishing (CMP).

Next, form second silicon nitride layer 64, which could be used as a sacrificial dielectric layer, both planarized surface of first inter-metal dielectric layer 63 and residual first silicon nitride layer 61 by using, for example, chemical vapor deposition (CVD). Thickness of the silicon nitride layer 64 is preferably about 8000-10000 angstrom. However, the practical thickness of the silicon nitride layer 64 depends on the required dimension of corresponding dual damascene structure. After that, for photoresist 65 on silicon nitride layer 64 by using photolithography techniques, where photoresist 65 totally overlay residual first silicon nitride layer 61. Therefore, by using photoresist 65 as a mask, second silicon nitride layer 64 is removed, for example by anisotropy etching process, until part of first inter-metal dielectric layer 63 is exposed.

Then, remove photoresist 65 and form second inter-metal dielectric layer 66, with a thickness about 12000-15000 angstroms, over both residual first inter-metal dielectric layer 63 and residual first silicon nitride 61. As usual, a planarization process such as chemical mechanical polishing (CMP) is used to planarize surface of second inter-metal dielectric layer 66. Second inter-metal dielectric layer 66 usually is formed by plasma enchanted chemical vapor deposition (PECVD) or high-density plasma chemical vapor deposition (HDPCVD).

Consequentially, use wet etch, a preferable etchant is hot phosphoric acid solution, to isotroptically etch remove residual second silicon nitride layers 64 and residual first silicon nitride layer 61 form hole 67, which has a profile like a T-profiled cavity. Consequentially, an optional step is to perform a blanket dry etch to ensure no silicon nitride is residual.

Finally, fill conductor layer 68 into hole 67. Material of the conductor layer 68 could be copper, tungsten, aluminum, silver, and alloys. Surely, an optional step is to form barrier layer 69, such as titanium nitride (TiN), on surface of hole 67 before conductor layer 68 is formed.

Although specific embodiments have been illustrated and described, it will be obvious to those skilled in the art that various modifications may be made without departing from what is intended to be limited solely by the appended claims.

What is claimed is:

1. A dual damascene process, comprising:
providing a substrate;
forming a first dielectric layer over said substrate;
forming a first photoresist over said first dielectric layer, wherein said first photoresist forms a continue structure which covers a portion of said first dielectric layer;
removing said first dielectric layer by using said first photoresist as a mask, such that residual part of said first dielectric layer covers a portion of said substrate;
removing said first photoresist;
forming a first inter-metal dielectric layer over both said substrate and residual part of said first dielectric layer;
planarizating said first inter-metal dielectric layer, such that residual part of said first dielectric layer is not covered by said first inter-metal dielectric layer;
forming a second dielectric layer over both said first inter-metal dielectric layer and residual part of said first dielectric layer;
forming a second photoresist over said second dielectric layer, wherein said second photoresist overlay residual part of said first dielectric layer;
removing said second dielectric layer by using said second photoresist as a mask, such that residual part of said second dielectric layer is overlaid over residual part of said first dielectric layer;
removing said second photoresist;
forming a second inter-metal dielectric layer over both said first inter-metal dielectric layer and residual part of said second dielectric layer;
planarizating said second inter-metal dielectric layer, such that residual part of said second dielectric layer is not covered by said second inter-metal dielectric layer;
removing both residual part of said first dielectric layer and residual part of said second dielectric layer, such that a hole is formed in both said first inter-metal dielectric layer and said second inter-metal layer;
forming a barrier layer over both said second inter-metal dielectric layer and said first inter-metal dielectric layer; and
forming a conductor layer in said hole.

2. The process according to claim 1, wherein said continue structure defines the location of a dual damascene structure.

3. The process according to claim 1, wherein said first dielectric layer is a silicon nitride layer.

4. The process according to claim 1, wherein said second dielectric layer is a silicon nitride layer.

5. The process according to claim 1, wherein said first inter-metal dielectric layer is a silicon dioxide layer.

6. The process according to claim 1, wherein said second inter-metal dielectric layer is a silicon dioxide layer.

7. The process according to claim 1, wherein said barrier layer is a TiN layer.

8. The process according to claim 1, wherein said barrier layer is a TiW layer.

9. The process according to claim 1, wherein said first inter-metal dielectric layer is planarized by a chemical mechanical polishing.

10. The process according to claim 1, wherein said first inter-metal dielectric layer is planarized by an etching process.

11. The process according to claim 1, wherein said second inter-metal dielectric layer is planarized by a chemical mechanical polishing.

12. The process according to claim 1, wherein said second inter-metal dielectric layer is planarized by an etching process.

13. A dual damascene process for forming a dual damascene structure, said damascene structure is a combination of a lower part and an upper part which is wider than said lower part, comprising:
providing a substrate;
forming a first model structure on said substrate, wherein the profile of said first model structure is equal to the profile of said lower part;
forming a first dielectric layer on part of said substrate which is not covered by said first model structure, wherein the height of said first dielectric layer is briefly equal to the height of said first model structure;
forming a second model structure on both said first model structure and part of said first dielectric layer, wherein the profile of said second model structure is equal to the profile of said upper part;
forming a second dielectric layer on part of said first dielectric layer which is not covered by said second model structure, wherein the height of said second dielectric layer is equal to the height of said second model structure;
removing both said second model structure and said first model structure, such that a hole is formed in both said first dielectric layer and said second dielectric layer; and
filling said hole by a conductor layer.

14. The process according to claim 13, further comprises forming a barrier layer on the surface of said hole before said hole is filled by said conductor layer.

15. The process according to claim 13, wherein said second model structure is removed by a wet etching process.

16. The process according to claim 13, wherein said first model structure is removed by a wet etching process.

17. The process according to claim 13, wherein said second model structure and said first model structure are removed by the same wet etching process and an additional blanket dry etching process.

18. A damascene process for forming a damascene structure, comprising:
providing a substrate;
forming a model structure on said substrate, wherein the profile of said structure is equal to the profile of said damascene structure;
forming a dielectric layer on part of said substrate which is not covered by said model structure, wherein the height of said first dielectric layer is equal to the height of said model structure;
removing said model structure, such that a hole is formed in said first dielectric layer; and
filling said hole by a conductor layer.

19. A dual damascene process, said process comprising:
providing a silicon substrate;
forming a first silicon nitride layer over said silicon substrate;
forming a first photoresist over said first silicon nitride layer, wherein said first photoresist forms a continue structure on said first silicon nitride layer;
removing said first silicon nitride layer by using said first photoresist as a mask;
forming a first inter-metal dielectric layer over both said substrate and residual said first silicon nitride;
planarizating said first inter-metal dielectric layer by a chemical mechanical polishing, such that residual said first silicon nitride layer is not covered by residual said first inter-metal dielectric layer;
removing said first photoresist;
forming a second silicon nitride layer on both residual said first silicon nitride layer and residual said first inter-metal dielectric layer;
forming a second photoresist over said second silicon nitride layer, wherein said second photoresist forms a continue structure on said second silicon nitride layer;
removing said second silicon nitride layer by using said second photoresist as a mask, such that residual said first silicon nitride layer is totally covered by residual said second silicon nitride layer;
removing said second photoresist;
forming a second inter-metal dielectric layer over both residual said first inter-metal dielectric layer and residual said second silicon nitride layer;
planarizating said second inter-metal dielectric layer by a chemical mechanical polishing, such that said second silicon nitride layer is not covered by said second inter-metal dielectric layer;
removing both residual said second silicon nitride layer and residual said first silicon nitride layer, such that a hole which has the profile of said damascene structure is formed in both said second inter-metal dielectric layer and said first inter-metal dielectric layer;
forming a barrier layer on both the top surface of residual first inter-metal dielectric layer and the surface of said hole;
filling said hole by a metal layer.

20. The process according to claim 19, wherein both residual said second silicon nitride layer and residual said first silicon nitride layer are removed by a wet etching process and a blank dry etching process in sequence.
